(19) United States
(12) Patent Application Publication
(10) Pub. No.: US 2024/0213794 A1
(43) Pub. Date: Jun. 27, 2024

(54) POWER CONTROL METHOD, AND ELECTRONIC DEVICE FOR PERFORMING SAME

(71) Applicant: Samsung Electronics Co., Ltd., Suwon-si (KR)

(72) Inventor: Hyunjun OH, Suwon-si (KR)

(21) Appl. No.: 18/602,552

(22) Filed: Mar. 12, 2024

Related U.S. Application Data
(63) Continuation of application No. PCT/KR2022/016854, filed on Oct. 31, 2022.

(30) Foreign Application Priority Data
Nov. 2, 2021 (KR) 10-2021-0148729
Oct. 28, 2022 (KR) 10-2022-0141855

(51) Int. Cl. H02J 7/00

(52) U.S. Cl. CPC H02J 7/007182; H02J 7/0029

(57) ABSTRACT

A power control method and an electronic device for performing the method are disclosed. A power control method according to various embodiments may comprise: receiving an input for turning off the power of an electronic device; identifying the voltage of a battery based on the input being received; determining, based on a set margin voltage and the voltage of the battery based on the input being received, a reference voltage for entering a ship mode preventing and/or reducing discharge of the battery caused by leakage current; turning off the power of the electronic device; monitoring the voltage of the battery after turning off the power of the electronic device; and setting the electronic device to the ship mode based on the monitored voltage of the battery and the reference voltage.

### CROSS-REFERENCE TO RELATED APPLICATIONS

This application is a continuation of International Application No. PCT/KR2022/016854 designating the United States, filed on Oct. 31, 2022, in the Korean Intellectual Property Receiving Office and claiming priority to Korean Patent Application Nos. 10-2021-0148729, filed on Nov. 2, 2021, and 10-2022-0141855, filed on Oct. 28, 2022, in the Korean Intellectual Property Office, the disclosures of each of which are incorporated by reference herein in their entireties.

### BACKGROUND

### Field

The disclosure relates to a power control method and an electronic device for performing the same.

### Description of Related Art

A ship mode may turn off all blocks (or a module) in an integrated circuit (IC) of an electronic device and may remove a leakage current of the electronic device by disconnecting a switch between a battery of the electronic device and an internal power system of the electronic device.

Since a leakage current does not occur in the ship mode, the electronic device may minimize and/or reduce the power consumed by an interface power management IC (IF PMIC), a charging module (or a charger), and/or a system. In the electronic device in the ship mode, wired or wireless charging may need to be recognized, a specific signal may need to be applied, or a power key of the electronic device may need to be pressed to cancel the ship mode.

When releasing an electronic device, a forced ship mode may be applied. The forced ship mode may refer to setting the electronic device to the ship mode using a ship mode command through an inter-integrated circuit (I2C) or other channels regardless of a voltage level of a battery.

A leakage current may be minimized/reduced from a time point when the electronic device enters the forced ship mode and a time taken for reaching battery overdischarge may significantly increase compared to a case in which the ship mode is not applied.

After an electronic device is manufactured, by setting the electronic device to enter a forced ship mode through a command using an inter-integrated circuit I2C or other channels before releasing the electronic device, a leakage current of the electronic device may be minimized/reduced and a time to battery overdischarge may increase, thereby a risk of battery swelling may decrease even if the electronic device is kept for a long period in an inbox state. However, when a user keeps an electronic device for a long time after turning off the power of the electronic device in use, a leakage current of the electronic device may not be minimized/reduced and there is a risk of battery overdischarge.

In the case of an electronic device in use by a user, various Android application packages (APKs) and programs may be installed in the electronic device depending on a user's use condition, and depending on a use condition of a power off sequence, for example, depending on a system operation or an APK operation when turning off the power, a time to completely turn off the power of the electronic device may increase. In the case of the electronic device in use, since a time of a power off sequence operation may vary depending on a use condition, the power off operation may not be normally terminated and a sudden power off event may occur when a forced ship mode for entering the ship mode after a predetermined time period has elapsed is applied. When entering the ship mode before the completion of the power off operation, malfunction of an integrated circuit (IC) or damage may be caused in the electronic device.

In the case of a structure in which a system and a battery are separated from each other and separately controlled, a fuel gauge IC may not be provided with power directly from the battery, and in the case of a structure in which the power is provided by a system end, the fuel gauge IC may be reset if the electronic device enters the ship mode whenever a user turns off the power of the electronic device. Since the fuel gauge, which has been reset when canceling the ship mode of the electronic device, estimates an initial state of charge (SOC) based on a terminal battery voltage, a problem that an SOC displayed through a user interface (UI) before and after turning off the power of the electronic device changes may occur.

### SUMMARY

Embodiments of the disclosure provide a power control method of monitoring a voltage of a battery after a power-off operation and setting an electronic device to a ship mode when the voltage of the battery after turning off the power is less than or equal to a voltage to enter the ship mode and an electronic device for performing the same.

Embodiments of the disclosure provide a power control method of entering a ship mode depending on a voltage level of a battery after a user turns off the power of an electronic device and neglects the electronic device for a long period and an electronic method for performing the same.

Embodiments of the disclosure provide a power control method of storing power gauge data and loading stored power gauge data when canceling a ship mode and an electronic device for performing the same.

Embodiments of the disclosure provide a power control method of setting an electronic device to a ship mode when a set time period has elapsed after a power-off operation and an electronic device for performing the same.

A power control method according to various example embodiments may include: receiving an input to turn off power of an electronic device, identifying a voltage of a battery based on receiving the input, determining a reference voltage to enter a ship mode to prevent and/or reduce discharge of the battery due to a leakage current based on a set margin voltage and a voltage of the battery when receiving the input, turning off the power of the electronic device, monitoring the voltage of the battery after turning off the power of the electronic device, and setting the electronic device to the ship mode based on a monitored voltage of the battery and the reference voltage.

A power control method according to various example embodiments may include: receiving an input to set an electronic device to a ship mode to prevent and/or reduce discharge of a battery due to a leakage current, turning off power of the electronic device, storing power gauge data related to a state of the battery in a memory, and setting the electronic device to the ship mode.

An electronic device according to various example embodiments may include: a battery, at least one processor, comprising processing circuitry, and a power management module comprising power management circuitry configured to control power output by the battery, wherein at least one processor, individually and/or collectively, is configured to receive an input to turn off power of an electronic device, identify a voltage of a battery based on receiving the input, determine a reference voltage to enter a ship mode to prevent and/or reduce discharge of the battery due to a leakage current based on a set margin voltage and a voltage of the battery when receiving the input, turn off the power of the electronic device, wherein the power management module is further configured to: monitor the voltage of the battery after turning off the power of the electronic device, and set the electronic device to the ship mode based on a monitored voltage of the battery and the reference voltage.

A power control method according to various example embodiments may include: identifying a signal to turn off power of an electronic device, turning off the power of the electronic device, counting a set first time period from when the signal to turn off the power is identified, and setting the electronic device to a ship mode to prevent and/or reduce discharge of a battery due to a leakage current.

According to a power control method and an electronic device for performing the same in various example embodiments, an electronic device may enter a ship mode depending on a use condition of the electronic device of a user when turning off the power of the electronic device.

According to a power control method and an electronic device for performing the same in various example embodiments, the stability of a battery and an electronic may be improved by causing the electronic device to enter the ship mode depending on a use condition of the electronic device of a user and the ship mode may be canceled without resetting fuel gauge data by storing the fuel gauge data before entering the ship mode.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a block diagram illustrating an example configuration of a power management module and a battery according to various embodiments;

FIG. 3 is a diagram illustrating an example operation of an electronic device according to various embodiments;

FIG. 4 is a flowchart illustrating example operations of an electronic device according to various embodiments;

FIG. 5 is a flowchart illustrating example operations of an electronic device according to various embodiments; and

FIG. 6 is a flowchart illustrating example operations of an electronic device according to various embodiments.

### DETAILED DESCRIPTION

Hereinafter, various example embodiments will be described in greater detail with reference to the accompanying drawings. When describing the various example embodiments with reference to the accompanying drawings, like reference numerals may refer to like elements and a repeated description related thereto may not be provided.

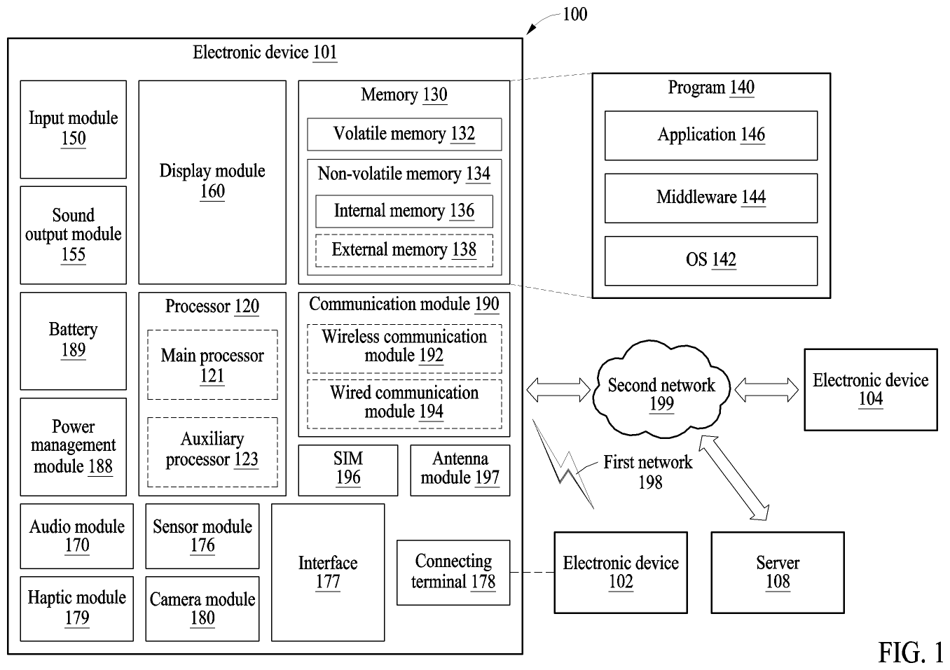

FIG. 1 is a block diagram illustrating an example electronic device 101 in a network environment 100 according to various example embodiments. Referring to FIG. 1, the electronic device 101 in the network environment 100 may communicate with an electronic device 102 via a first network 198 (e.g., a short-range wireless communication network), or communicate with at least one of an electronic device 104 or a server 108 via a second network 199 (e.g., a long-range wireless communication network). According to an example embodiment, the electronic device 101 may communicate with the electronic device 104 via the server 108. According to an embodiment, the electronic device 101 may include a processor 120, a memory 130, an input module 150, a sound output module 155, a display module 160, an audio module 170, and a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one (e.g., the connecting terminal 178) of the above components may be omitted from the electronic device 101, or one or more other components may be added to the electronic device 101. In various embodiments, some (e.g., the sensor module 176, the camera module 180, or the antenna module 197) of the components may be integrated as a single component (e.g., the display module 160).

The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may execute, for example, software (e.g., a program 140) to control at least one other component (e.g., a hardware or software component) of the electronic device 101 connected to the processor 120, and may perform various data processing or computation. According to an embodiment, as at least a part of data processing or computation, the processor 120 may store a command or data received from another component (e.g., the sensor module 176 or the communication module 190) in a volatile memory 132, process the command or the data stored in the volatile memory 132, and store resulting data in a non-volatile memory 134. According to an embodiment, the processor 120 may include a main processor 121 (e.g., a central processing unit (CPU) or an application processor (AP)) or an auxiliary processor 123 (e.g., a graphics processing unit (GPU), a neural processing unit (NPU), an image signal processor (ISP), a sensor hub processor, or a communication processor (CP)) that is operable independently from, or in conjunction with the main processor 121. For example, when the electronic device 101 includes the main processor 121 and the auxiliary processor 123, the auxiliary processor 123 may be adapted to consume less power than the main processor 121 or to be specific to a specified function. The auxiliary processor 123 may be implemented separately from the main processor 121 or as a part of the main processor 121.

The auxiliary processor 123 may control at least some of functions or states related to at least one (e.g., the display module 160, the sensor module 176, or the communication module 190) of the components of the electronic device 101, instead of the main processor 121 while the main processor 121 is in an inactive (e.g., sleep) state or along with the main processor 121 while the main processor 121 is an active state (e.g., executing an application). According to an embodiment, the auxiliary processor 123 (e.g., an ISP or a CP) may be implemented as a portion of another component (e.g., the camera module 180 or the communication module 190) that is functionally related to the auxiliary processor 123. According to an embodiment, the auxiliary processor 123 (e.g., an NPU) may include a hardware structure specified for artificial intelligence (AI) model processing. An AI model may be generated through machine learning. Such learning may be performed by, for example, the electronic device 101 in which artificial intelligence is performed, or performed via a separate server (e.g., the server 108). Learning algorithms may include, but are not limited to, for example, supervised learning, unsupervised learning, semi-supervised learning, or reinforcement learning. The AI model may include a plurality of artificial neural network layers. An artificial neural network may include, for example, a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more thereof, but is not limited thereto. The AI model may additionally or alternatively include a software structure other than the hardware structure.

The memory 130 may store various data used by at least one component (e.g., the processor 120 or the sensor module 176) of the electronic device 101. The various pieces of data may include, for example, software (e.g., the program 140) and input data or output data for a command related thereto. The memory 130 may include the volatile memory 132 or the non-volatile memory 134.

The program 140 may be stored as software in the memory 130 and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output a sound signal to the outside of the electronic device 101. The sound output module 155 may include, for example, a speaker or a receiver. The speaker may be used for general purposes, such as playing multimedia or playing record. The receiver may be used to receive an incoming call. According to an embodiment, the receiver may be implemented separately from the speaker or as a part of the speaker.

The display module 160 may visually provide information to the outside (e.g., a user) of the electronic device 101. The display module 160 may include, for example, a display, a hologram device, or a projector and control circuitry to control a corresponding one of the display, the hologram device, and the projector. According to an embodiment, the display module 160 may include a touch sensor adapted to sense a touch, or a pressure sensor adapted to measure an intensity of a force incurred by the touch.

The audio module 170 may convert a sound into an electrical signal or vice versa. According to an embodiment, the audio module 170 may obtain the sound via the input module 150 or output the sound via the sound output module 155 or an external electronic device (e.g., an electronic device 102 such as a speaker or headphones) directly or wirelessly connected to the electronic device 101.

The sensor module 176 may detect an operational state (e.g., power or temperature) of the electronic device 101 or an environmental state (e.g., a state of a user) external to the electronic device 101, and generate an electric signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., by wire) or wirelessly. According to an embodiment, the interface 177 may include, for example, a high-definition multimedia interface (HDMI), a universal serial bus (USB) interface, a secure digital (SD) card interface, or an audio interface.

The connecting terminal 178 may include a connector via which the electronic device 101 may be physically connected to an external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electric signal into a mechanical stimulus (e.g., a vibration or a movement) or an electrical stimulus which may be recognized by a user via his or her tactile sensation or kinesthetic sensation. According to an embodiment, the haptic module 179 may include, for example, a motor, a piezoelectric element, or an electric stimulator.

The camera module 180 may capture a still image and moving images. According to an embodiment, the camera module 180 may include one or more lenses, image sensors, ISPs, or flashes.

The power management module 188 may manage power supplied to the electronic device 101. According to an embodiment, the power management module 188 may be implemented as, for example, at least a part of a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more CPs that are operable independently from the processor 120 (e.g., an AP) and that support a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module, or a power line communication (PLC) module). A corresponding one of these communication modules may communicate with the external electronic device 104 via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., a LAN or a wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the SIM 196.

The wireless communication module 192 may support a 5G network after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., a mmWave band) to achieve, e.g., a high data transmission rate. The wireless communication module 192 may support various technologies for securing performance on a high-frequency band, such as, e.g., beamforming, massive multiple-input and multiple-output (MIMO), full dimensional MIMO (FD-MIMO), an array antenna, analog beam-forming, or a large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., an external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in a communication network, such as the first network 198 or the second network 199, may be selected by, for example, the communication module 190 from the plurality of antennas. The signal or power may be transmitted or received between the communication module 190 and the external electronic device via the at least one selected antenna. According to an embodiment, another component (e.g., a radio frequency integrated circuit (RFIC)) other than the radiating element may be additionally formed as a part of the antenna module 197.

According to an embodiment, the antenna module 197 may form a mmWave antenna module. According to an embodiment, the mmWave antenna module may include a PCB, an RFIC disposed on a first surface (e.g., a bottom surface) of the PCB or adjacent to the first surface and capable of supporting a designated a high-frequency band (e.g., a mmWave band), and a plurality of antennas (e.g., array antennas) disposed on a second surface (e.g., a top or a side surface) of the PCB, or adjacent to the second surface and capable of transmitting or receiving signals in the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the external electronic devices 102 and 104 may be a device of the same type as or a different type from the electronic device 101. According to an embodiment, all or some of operations to be executed by the electronic device 101 may be executed at one or more external electronic devices (e.g., the external electronic devices 102 and 104, and the server 108). For example, if the electronic device 101 needs to perform a function or a service automatically, or in response to a request from a user or another device, the electronic device 101, instead of, or in addition to, executing the function or the service, may request one or more external electronic devices to perform at least part of the function or the service. The one or more external electronic devices receiving the request may perform the at least part of the function or the service requested, or an additional function or an additional service related to the request, and may transfer an outcome of the performing to the electronic device 101. The electronic device 101 may provide the result, with or without further processing the result, as at least part of a response to the request. To that end, cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., a smart home, a smart city, a smart car, or healthcare) based on 5G communication technology or IoT-related technology.

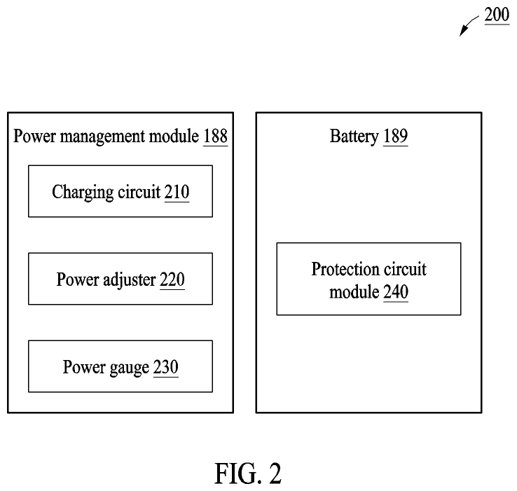

FIG. 2 is a block diagram 200 illustrating an example configuration of the power management module (e.g., including power management circuitry) 188 and the battery 189 according to various embodiments. Referring to FIG. 2, the power management module 188 may include a charging circuit 210, a power adjuster (e.g., including various circuitry and/or executable program instructions) 220, and/or a power gauge 230. The charging circuit 210 may charge the battery 189 using power supplied from an external power source outside the electronic device 101. According to an embodiment, the charging circuit 210 may select a charging scheme (e.g., normal charging or quick charging) based at least in part on a type of the external power source (e.g., a power outlet, a USB, or wireless charging), magnitude of power suppliable from the external power source (e.g., about 20 Watts or more), or an attribute of the battery 189, and may charge the battery 189 using the selected charging scheme. The external power source may be connected with the electronic device 101, for example, by wire via the connecting terminal 178 or wirelessly via the antenna module 197.

For example, the power adjuster 220 may include various circuitry and/or executable program instructions and generate pieces of power having different voltage levels or different current levels by adjusting a voltage level or a current level of the power supplied from the external power source or the battery 189. The power adjuster 220 may adjust the voltage level or the current level of the power supplied from the external power source or the battery 189 into a different voltage level or current level appropriate for each of some of the components included in the electronic device 101. According to an embodiment, the power adjuster 220 may be implemented in the form of a low drop out (LDO) regulator or a switching regulator. The power gauge 230 may measure use state information about the battery 189 (e.g., the capacity, the number of times charging or discharging, voltage, or the temperature of the battery 189).

The power management module 188 may determine, using, for example, the charging circuit 210, the power adjuster 220, or the power gauge 230, charging state information (e.g., lifetime, over voltage, low voltage, over current, over charge, over discharge, overheat, short, or swelling) related to the charging of the battery 189 based at least in part on the measured use state information about the battery 189. The power management module 188 may determine whether the state of the battery 189 is normal or abnormal based at least in part on the determined charging state information. If the state of the battery 189 is determined to be abnormal, the power management module 188 may adjust the charging of the battery 189 (e.g., reduce the charging current or voltage, or stop the charging). According to an embodiment, at least some of the functions of the power management module 188 may be performed by an external control device (e.g., the processor 120).

According to an embodiment, the battery 189 may include a protection circuit module (PCM) 240. The PCM 240 may perform one or more of various functions (e.g., a pre-cutoff function) to prevent and/or reduce performance deterioration of, or a damage to, the battery 189. The PCM 240, additionally or alternatively, may be configured as at least part of a battery management system (BMS) capable of performing various functions including cell balancing, measurement of battery capacity, count of the number of charging or discharging cycles, measurement of temperature, or measurement of voltage.

According to an embodiment, at least part of the charging state information or use state information regarding the battery 189 may be measured using a corresponding sensor (e.g., a temperature sensor) of the sensor module 276, the power gauge 230, or the power management module 188. According to an embodiment, the corresponding sensor (e.g., a temperature sensor) of the sensor module 176 may be included as part of the PCM 140, or may be disposed near the battery 189 as a separate device.

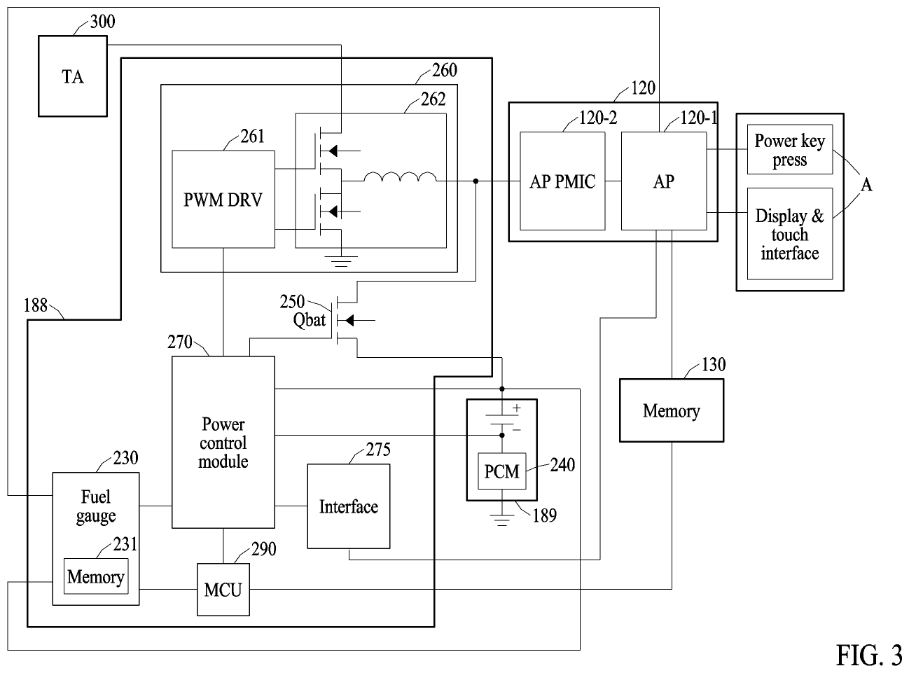

FIG. 3 is a diagram illustrating an example operation of an electronic device (e.g., the electronic device 101 of FIG. 1) according to various embodiments.

Referring to FIG. 3, the electronic device 101 in various embodiments may include the processor (e.g., including processing circuitry) 120, the power management module (e.g., including power management circuitry) 188, the battery 189, and the memory 130.

According to various embodiments, the processor 120 may include an application processor (AP) (e.g., including processing circuitry) 120-1 and an AP power management integrated chip (PMIC) (e.g., including PMIC circuitry) 120-2. For example, the AP PMIC 120-2 may supply power to components of the electronic device 101, such as the AP 120-1 and/or an integrated circuit (IC) using power input by the battery 189. For example, the AP PMIC 120-2 may convert power input by the battery 189 to supply the power required for a component of the electronic device 101. For example, a voltage of the power required for the AP 120-1 may vary depending on an internal configuration of the AP 120-1 and/or an operation state of the AP 120-1, and the AP PMIC 120-2 may supply the power required for the internal configuration of the AP 120-1 by converting the input power.

According to various embodiments, the power management module 188 may include a charging circuit 260, the power gauge 230, a switch 250, a power control module (e.g., including power control circuitry) 270, an interface module (e.g., including interface circuitry) 275, and a microcontroller unit (MCU) (e.g., including various control and/or processing circuitry) 290.

For example, the charging circuit 260 may charge the battery 189 using power input from the outside or may supply power to the processor 120. An operation of the charging circuit 260 may be controlled by the power control module 270. For example, based on the control of the power control module 270, power may be supplied to the battery 189 and/or the processor 120 by converting external power input to the charging circuit 260. For example, the charging circuit 260 may include a pulse width modulation driver (PWM DRV) 261 and a buck converter 262. For example, the PWM DRV 261 may be operated by a control signal provided by the power control module 270. The PWM DRV 261 may be operated based on the control signal and may supply the external power input from an adapter 300 (e.g., a TA of FIG. 3) to the buck converter 262, and the supplied external power may be converted by the buck converter 262.

For example, the switch 250 may form a path to supply power from the battery 189 to components in the electronic device 101. For example, when the switch 250 is in an on state, power may be supplied to the processor 120 from the battery 189.

The example of FIG. 3 illustrates a case in which a target to be supplied with power from the power management module 188 is the processor 120, like a case in which power input from the outside is used to charge the battery 189 and/or is supplied to the processor 120 by converting the power using the charging circuit 260 or a case in which the power is supplied to the processor 120 using power charged in the battery 189.

The example of FIG. 3 may correspond to any of various embodiments and, the power output from the battery 189 may be supplied to components of the electronic device 101, such as an IC other than the processor 120, a display module (e.g., the display module 160 of FIG. 1), a sound output module (e.g., the sound output module 155 of FIG. 1), a communication module (e.g., the communication module 190 of FIG. 1), an audio module (e.g., the audio module 170 of FIG. 1), a sensor module (e.g., the sensor module 176 of FIG. 1), a haptic module (e.g., the haptic module 179 of FIG. 1), or a camera module (e.g., the camera module 180 of FIG. 1). In addition to the examples described above, the power output from the battery 189 may be supplied to components included in the electronic device 101, such as the memory 130, an antenna module (e.g., the antenna module 197 of FIG. 1), and an input module (e.g., the input module 150 of FIG. 1).

For example, when a voltage magnitude to be supplied to a component in the electronic device 101 is different from a voltage magnitude output from the power management module 188 and/or the battery 189, the electronic device 101 may include a conversion module configured to convert power output from the power management module 188 and/or the battery 189.

For example, the processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may, for example, receive a user input to turn off the power of the electronic device 101. The processor 120 may receive a user input A to turn off the power of the electronic device 101 through a power key input of the electronic device 101 or an interface of a display module (e.g., the display module 160 of FIG. 1).

For example, the processor 120 may identify a voltage of the battery 189 when receiving the user input A. For example, the power control module 270 may identify a voltage of the battery 189. When receiving a user input, the processor 120 may identify a voltage of the battery 189 from the power control module 270.

For example, the processor 120 may set a reference voltage to enter a ship mode. For example, when receiving the user input A to turn off the power of the electronic device 101 and a set margin voltage, the processor 120 may determine a reference voltage based on the identified voltage of the battery 189.

According to an embodiment, when a maximum charging voltage of the battery 189 is 4.4 V and a cut-off voltage of the PCM 240 is 2.5 V, the electronic device 101 may determine a reference voltage from 20 voltage levels in the unit of 0.1 V within a range between the maximum charging voltage and the cut-off voltage. For example, when the identified voltage of the battery 189 is 4.0 V and the set margin voltage is 300 mV, the electronic device 101 may determine the reference voltage to be 3.7 V. In another example, when the identified voltage of the battery 189 is 3.94 V and the set margin voltage is 300 mV, the electronic device 101 may determine the reference voltage to be 3.6 V, which is a voltage level less than a voltage obtained by subtracting the margin voltage from the voltage of the battery 189.

According to various embodiments, the processor 120 may determine the reference voltage such that the reference voltage is greater than or equal to the cut-off voltage. As described above, the processor 120 may determine the reference voltage depending on a voltage magnitude obtained by subtracting a margin voltage from a voltage of the battery 189 when receiving a user input.

For example, the processor 120 may set a margin voltage by considering a cut-off voltage of the battery 189 and a voltage range of the battery 189 when the electronic device 101 is in a normal operation. For example, when the voltage range of the battery 189 when the electronic device 101 is in a normal operation is greater than or equal to 3.3 V and less than or equal to 4.4 V and the cut-off voltage of the battery 189 is 2.5 V, the processor 120 may set a margin voltage to be less than or equal to 0.8 V, which is a voltage magnitude obtained by subtracting a cut-off voltage of the battery 189, 2.5 V, from a minimum voltage magnitude of the voltage range of the battery 189, 3.3 V. The processor 120 may determine the reference voltage to be greater than or equal to the cut-off voltage using the margin voltage that is set by considering the voltage range of the battery 189 and the cut-off voltage of the battery 189.

The example in which the reference voltage is determined based on the margin voltage and the voltage of the battery 189 from voltage levels in the set unit between the maximum charging voltage of the battery 189 and the cut-off voltage of the PCM 240 may be one of various embodiments and the electronic device 101 may determine the reference voltage in a different method from the example described above. In another example, when the voltage of the battery 189 is 3.94 V and the set margin voltage is 300 mV, the reference voltage may be determined to be 3.64 V, or when the voltage of the battery 189 is greater than or equal to 3 V and less than or equal to 3.3 V, the reference voltage may be determined to be 2.7 V.

According to various embodiments, the electronic device 101 may prevent and/or reduce or block the electronic device 101 from being set to the ship mode before the user input A to turn off the power of the electronic device 101 is received. Since the user uses the electronic device 101 before the user input to turn off the power is received, the power may need to be supplied to components of the electronic device 101.

For example, the electronic device 101 may set the reference voltage before the user input to turn off the power is received by considering the cut-off voltage of the battery 189. For example, the cut-off voltage of the battery 189 may be a voltage at which the PCM 240 operates to prevent and/or reduce overdischarge of the battery 189.

For example, the electronic device 101 may turn off the power. Turning off the power of the electronic device 101 may represent that a program or an operating system (OS) executed by the processor 120 is terminated and the power supplied to components in the electronic device 101, such as the processor 120, an IC, a display module, a sound output module, a communication module, an audio module, a sensor module, a haptic module, or a camera module, is blocked.

For example, the power management module 188 may monitor a voltage of the battery 189 after turning off the power of the electronic device 101. After the power of the electronic device 101 is turned off, the power may not be supplied to components in the electronic device 101, such as the processor 120, but the voltage of the battery 189 may drop due to a leakage current. For example, after turning off the power, the voltage of the battery 189 monitored by the power management module 188 may gradually decrease.

For example, the power management module 188 may determine whether to change the electronic device 101 to be in a ship mode based on the monitored voltage of the battery 189 and a reference voltage to enter the ship mode.

For example, when the monitored voltage of the battery 189 is less than or equal to the reference voltage, the power management module 188 may set the electronic device 101 to the ship mode. For example, when the voltage of the battery 189 is 3.9 V and the set reference voltage is 3.6 V at the time of receiving the user input to turn off the electronic device 101, the voltage of the battery 189 may gradually decrease due to a leakage current after the power of the device is turned off. When the monitored voltage of the battery 189 is less than or equal to 3.6 V, the power management module 188 may set the electronic device 101 to the ship mode. For example, a case in which the voltage of the battery 189 becomes less than or equal to the reference voltage because of a voltage decrease due to a leakage current may represent a state in which the electronic device 101 has not been used for a long time.

For example, when the monitored voltage of the battery 189 is maintained to be less than or equal to the reference voltage for more than or equal to a set debounce time, the power management module 188 may set the electronic device 101 to the ship mode. For example, the debounce time may be set to be one of 1, 4, 16, 32, and 64 seconds. The above example of the debounce time may be one of various embodiments and as an example different from the above example, the debounce time may be variously set, such as 1 hour or 24 hours.

For example, the power management module 188 may check the leakage current of the electronic device 101 to determine that the power of the electronic device 101 is turned off when entering the ship mode. For example, the leakage current of the electronic device 101 may be a current output from the battery 189 when the electronic device 101 is turned off.

The power management module 188 in various embodiments may control an operation of the switch 250. The power management module 188 may set the electronic device 101 to the ship mode by controlling the operation of the switch 250. For example, the switch 250 may be connected to the battery 189 and may transmit the power to the electronic device 101. For example, the switch 250 may form a path to transmit the power output by the battery 189 to components (e.g., the processor 120, an IC, the display module 160, the sound output module 155, the communication module 190, the audio module 170, the sensor module 176, the haptic module 179, and the camera module 180) of the electronic device 101.

For example, the power management module 188 may turn off the switch 250. When the switch 250 is turned off, a path through which the leakage current flows from the battery 189 to components of the electronic device 101 may be blocked. For example, the power management module 188 may turn off the switch 250 and may set the electronic device 101 to the ship mode.

The electronic device 101 in various embodiments may store power gauge data related to a state of the battery 189 in a memory 130 or 231. For example, the power management module 188 may store the power gauge data in the memory 130 or 231 of the power gauge 230 using the MCU 290. For example, the power management module 188 may store the power gauge data in the memory 130 or 231 using the MCU 290.

In another example, the processor 120 may store the power gauge data in the memory 130. For example, the processor 120 may identify the power gauge data through the interface module 275 of the power management module 188 and may store the identified power gauge data in the memory 130.

The ship mode of the electronic device 101 in various embodiments may be canceled when a power key is input or the adapter 300 is inserted. For example, the power management module 188 may identify that a power key is input in the ship mode or external power is input through the adapter 300.

For example, when the power key is input, the power management module 188 may receive a power key input. For example, the power control module 270 of the power management module 188 may be connected to the power key. For example, when the adapter 300 is inserted, the power management module 188 may identify that external power is input through the adapter 300. For example, the power control module 270 of the power management module 188 may identify that external power is input by sensing a voltage and/or a voltage of the input external power. For example, the power management module 188 may cancel the ship mode of the electronic device 101 by turning on the switch 250 when the power key is input or the adapter 300 is inserted.

The electronic device 101 in various embodiments may load the power gauge data from the memory 130 or 231 when the ship mode is canceled. Loading the power gauge data from the memory 130 or 231 may refer to identifying the power gauge data stored in the memory 130 or 231.

For example, when the ship mode of the electronic device 101 is canceled, the power gauge 230 may load the power gauge data stored in the memory 231 of the power gauge 230. In another example, when the ship mode of the electronic 101 is canceled, the power control module 270 may identify the power gauge data stored in the memory 130 through the interface module 275 and the power gauge 230 may load the power gauge data from the power control module 270.

According to various embodiments, the power gauge data may be prevented or blocked from being initialized by storing the power gauge data in the memory when the electronic device 101 is set to the ship mode or before the electronic device 101 is set to the ship mode, and loading the power gauge data when the ship mode of the electronic device 101 is canceled or after the ship mode of the electronic device 101 is canceled.

The power gauge 230 in various embodiments may be electrically connected to the processor 120 and/or the battery 189. For example, the processor 120 may be electrically connected to the power gauge 230 and may identify the power gauge data, which is information on the state of the battery 189. In another example, the processor 120 may communicate with the power control module 270 through the interface 275 and may identify the power gauge data stored in the power gauge 230 from the power control module 270.

For example, the power gauge 230 may be electrically connected to the battery 189 and may measure use state information (e.g., the capacity, the number of charge and discharge cycles, the voltage, or the temperature of the battery 189) on the battery 189.

The electronic device 101 in various embodiments may control the electronic device 101 to prevent the electronic device 101 from being set to the ship mode in an operation before a user input to turn off the power of the electronic device 101 is received. Since a user uses the electronic device 101 before the user input to turn off the power is received, the electronic device 101 may control the electronic device 101 to prevent the electronic device 101 from being set to the ship mode.

For example, when the electronic device 101 is turned on, the reference voltage may be set to a default level. For example, when the electronic device 101 operates at a voltage of the battery 189 between 3.4 V and 4.4 V, the reference voltage set to the default level may be a low value, such as 2.6 V.

For example, the electronic device 101 may set the reference voltage by considering a cut-off voltage of the battery 189. For example, when the electronic device 101 operates at a voltage of the battery 189 between 3.4 V and 4.4 V, the electronic device 101 may be automatically turned off until the voltage of the battery 189 reaches 3.4 V. After the electronic device 101 is turned off, the battery 189 may be discharged for a long period. For example, when the voltage of the battery 189 reaches a cut-off voltage, the PCM 240 may operate to prevent and/or reduce overdischarge of the battery 189. For example, when the cut-off voltage of the battery 189 is 2.5 V, the electronic device 101 may set the reference voltage, such as 2.6 V or 2.7 V, by considering the cut-off voltage of the battery 189.

For example, when the reference voltage is set by considering the cut-off voltage of the battery 189 and the user uses the electronic device 101, the electronic device 101 may not be set to the ship mode.

For example, when the reference voltage is set by considering the cut-off voltage of the battery 189 and the battery 189 reaches the reference voltage as the battery 189 is continuously discharged after the electronic device 101 is automatically turned off, the electronic device 101 may be set to the ship mode.

For example, the electronic device 101 may disable a function that the power management module 188 sets the electronic device 101 to be in the ship mode. For example, when the power of the electronic device 101 is turned on and the user uses the electronic device 101, the power management module 188 may disable the function to set the electronic device 101 to be in the ship mode. For example, when an input to turn off the power of the electronic device 101 is received from the user, the electronic device 101 may enable the function of the power management module 188 to set the electronic device 101 to the ship mode.

Referring to FIG. 3, the electronic device 101 in an embodiment may identify a signal to turn off the power of the electronic device 101. For example, the electronic device 101 may identify a signal to turn off the power of the electronic device 101 from a user input to turn off the power of the electronic device 101, such as a power key input (e.g., power key press of FIG. 3) or a display and touch interface (e.g., a display and touch interface of FIG. 3).

For example, the electronic device 101 may determine a change in a state of the electronic device 101 during a set second time period. When the state of the electronic device 101 does not change during the second time period, the electronic device 101 may output a signal to turn off the power.

For example, the electronic device 101 may determine whether the state of the electronic device 101 has changed based on a screen touch input through a display module (e.g., the display module 160 of FIG. 1), a key input, such as a power key or a volume adjustment key, connection to a wired or wireless charger, an operating status of the electronic device 101 or an external environmental status collected by a sensor module (e.g., the sensor module 176 of FIG. 1), and a motion of a terminal (e.g., a motion of a terminal collected using a gyro sensor of the sensor module 176).

For example, when there is no screen touch input, key input, connection to a charger, a change in the operating status of the electronic device 101, and a change in the motion of the terminal during the second time period, it may be determined that there is no change in the state of the electronic device 101.

For example, when the signal to turn off the power is identified, the electronic device 101 may perform an operation to turn off the power of the electronic device 101. The electronic device 101 may terminate a running program or an OS and may block the power supplied to components, such as the processor 120, an IC, and the display module 160 in the electronic device 101.

For example, the electronic device 101 may count a set first time period from the time at which the signal to turn off the power is identified. For example, when the processor 120 identifies the signal to turn off the power, the processor 120 may transmit a control signal to the power management module 188. For example, the processor 120 may transmit the control signal to the power management module 270 through the interface module 275.

For example, the power management module 188 may count the set first time period based on the control signal. For example, the power control module 270 of the power management module 188 may count the set first time period.

For example, the electronic device 101 may determine the first time period based on a voltage magnitude of the battery 189. For example, the processor 120 may identify the voltage magnitude of the battery 189 when identifying the signal to turn off the power. For example, the processor 120 may determine the first time period having a positive correlation with the voltage magnitude of the battery 189 when identifying the signal to turn off the power.

For example, a voltage range of the battery 189 may be between about 3.3 V and about 4.4 V. For example, in a case in which the voltage magnitude of the battery 189 is 4.4 V when the signal to turn off the power is identified, the processor 120 may set the first time period to be 48 hours. For example, when the voltage magnitude of the battery 189 is 3.3 V at the time of identifying a signal to turn off the power, the processor 120 may determine the first time period to be 24 hours.

In the example described above, the first time period determined based on the voltage range of the battery 189 and the voltage magnitude of the battery 189 is an example and the example is not limited thereto.

For example, the electronic device 101 may set the electronic device 101 to the ship mode after the first time period has elapsed. For example, after the first time period has elapsed, the power control module 270 may set the electronic device 101 to the ship mode. For example, the power control module 270 may set the electronic device 101 to the ship mode by controlling an operation of the switch 250.

For example, after the first time period has elapsed, the electronic device 101 may set the electronic device 101 to the ship mode by turning off the switch 250. The power management module 188 may turn off the switch 250. When the switch 250 is turned off, a path through which the leakage current flows from the battery 189 to components of the electronic device 101 may be blocked. The power management module 188 may set the electronic device 101 to the ship mode by turning off the switch 250.

For example, the electronic device 101 may store power gauge data related to a state of the battery 189 in the memory 231. For example, the power control module 270 may store the power gauge data in the memory 231. For example, the power control module 270 may store the power gauge data in the memory 231 simultaneously with an operation of setting the electronic device 101 to the ship mode or may store the power gauge data in the memory 231 before or after the operation of setting the electronic device to the ship mode.

For example, when a power key is input or an adapter is inserted within the first time period, the electronic device 101 may stop counting the first time period.

For example, the electronic device 101 may set a mode to set the electronic device 101 to the ship mode based on a user input. For example, when setting to the mode to set to the ship mode, the electronic device 101 may be set to the ship mode after the first time period has elapsed after the power is turned off. For example, when the mode to set to the ship mode is not set, the electronic device 101 may not be set to the ship mode even if the first time period has elapsed after the power is turned off.

For example, when the power of the electronic device 101 is turned off based on a user input, the electronic device 101 may provide an interface to select the mode to set to the ship mode through the display module 160. For example, when a user desires to turn off the power of the electronic device 101 by inputting a power key, an interface to select power off, restart, power off, and enter ship mode may be provided.

For example, when identifying a signal to turn off the power depending on a change in a state of the electronic device 101 during the second time period, the electronic device 101 may operate based on a preset option regarding whether to enter the ship mode.

When a power key is input or an adapter is inserted after being set to the ship mode, the electronic device 101 may control the switch 250 that controls a path to transmit the power from the battery 189. The electronic device 101 may load the power gauge data stored in the memory 130 or 231.

When a power key is input or an adapter is inserted after being set to the ship mode, the electronic device 101 may cancel the ship mode of the electronic device 101 by turning on the switch 250. The power management module 188 may cancel the ship mode of the electronic device 101 by turning on the switch 250 when the power key is input or the adapter 300 is inserted.

Referring to the description of FIG. 3 provided above, the electronic device 101 may be set to the ship mode after the power is turned off. According to an embodiment, the electronic device 101 may be set to the ship mode based on a voltage magnitude of the battery 189 after the power is turned off. According to an embodiment, the electronic device 101 may be set to the ship mode after the set first time period has elapsed after the power is turned off.

The electronic device 101 may stably secure a time to turn off the power of the electronic device 101 while increasing a standby time from a state in which the power is turned off to overdischarge of the battery 189 by being set to the ship mode based on the voltage magnitude of the battery 189 or the set first time period. In the example embodiment shown in FIG. 3, by securing the time to turn off the power of the electronic device 101, an anomaly of an internal component of the electronic device 101 that may occur as the electronic device 101 enters the ship mode before the power is completely turned off may be prevented and/or reduced.

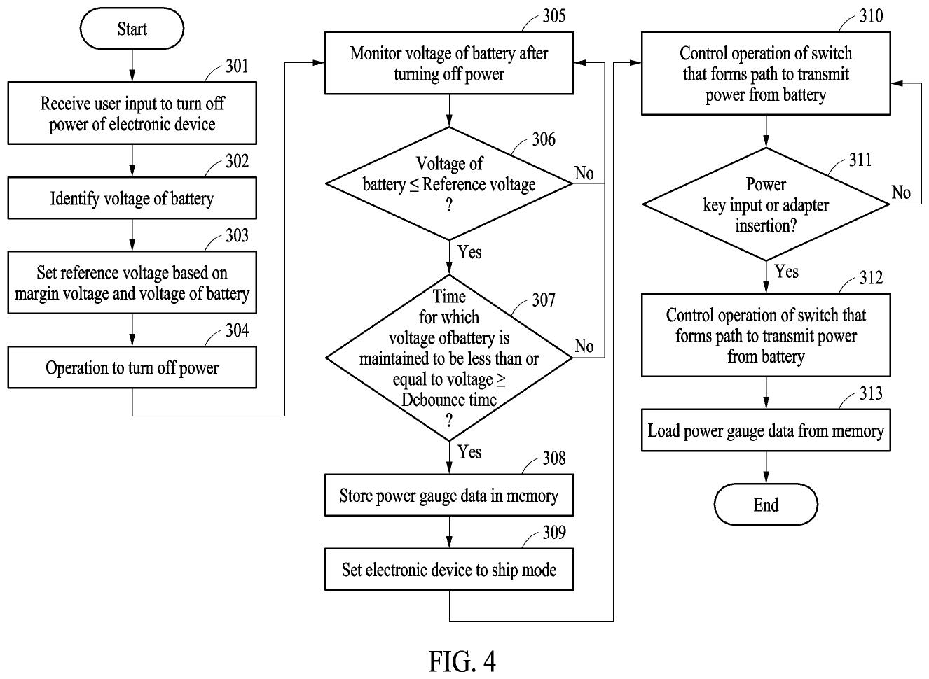

FIG. 4 is a flowchart illustrating example operations of an electronic device (e.g., the electronic device 101 of FIG. 1) according to various embodiments.

Referring to FIG. 4, in operation 301, the electronic device 101 in various embodiments may receive an input, e.g., a user input, to turn off the power of the electronic device 101. For example, the user input to turn off the power of the electronic device 101 may include a power key input of the electronic device 101 or an input through an interface displayed on a display module (e.g., the display module 160 of FIG. 1).

For example, in operation 302, the electronic device 101 may identify a voltage of a battery (e.g., the battery 189 of FIG. 1). The voltage of the battery 189 identified by the electronic device 101 in operation 302 may be a voltage of the battery 189 when receiving a user input to turn off the electronic device 101. For example, a power management module (e.g., the power management module 188 of FIG. 1) may identify a voltage of the battery 189 and the processor 120 may identify the voltage of the battery 189 from the power management module.

For example, in operation 303, the electronic device 101 may set a reference voltage based on a margin voltage and the voltage of the battery 189. The reference voltage may be a threshold to determine whether to set the electronic device 101 to the ship mode by the power management module.

For example, the electronic device 101 may set the reference voltage using a magnitude obtained by subtracting the margin voltage from the identified voltage of the battery 189. For example, the magnitude of the margin voltage may be set to a designated value.

For example, in operation 304, the electronic device 101 may perform an operation to turn off the power. For example, the electronic device 101 may terminate an OS or a program executed by a processor (e.g., the processor 120 of FIG. 1) to turn off the power. For example, when the electronic device 101 performs the operation to turn off the power, the power supply to components of the electronic device 101, such as the processor 120, may be stopped.

For example, in operation 305, the electronic device 101 may monitor the voltage of the battery 189 after turning off the power. For example, the power management module may identify the voltage of the battery 189 after turning off the power. Even after the power of the electronic device 101 is turned off, the voltage of the battery 189 may gradually drop due to a leakage current.

For example, the electronic device 101 may determine whether the voltage of the battery 189 is less than or equal to the reference voltage in operation 306. According to an embodiment, the electronic device 101 may determine whether the voltage of the battery 189 is less than or equal to the reference voltage at a predetermined cycle. For example, when the voltage of the battery 189 is less than or equal to the reference voltage in operation 306, in operation 307, the electronic device 101 may determine whether the time, for which the voltage of the battery 189 is maintained to be less than or equal to the reference voltage, is greater than or equal to the debounce time.

In operation 306 or 307, when the voltage of the battery 189 is greater than the reference voltage or the time, for which the voltage of the battery 189 is maintained to be less than or equal to the reference voltage, is less than the debounce time, the electronic device 101 may monitor the voltage of the battery 189 in accordance with operation 305. According to an embodiment, the electronic device 101 may monitor at a predetermined cycle whether the voltage of the battery 189 is less than or equal to the reference voltage and the time, for which the voltage of the battery 189 is maintained to be less than or equal to the reference voltage, is greater than the debounce time.

For example, in operation 308, the electronic device 101 may store the power gauge data in a memory (e.g., the memory 130 or 231 of FIG. 3). For example, the power gauge data may include use state information (e.g., the capacity, the number of charging and discharging cycles, the voltage, or the temperature of the battery 189) on the battery 189 or charging state information (e.g., lifetime, overvoltage, low voltage, low current, over current, overcharge, overdischarge, overheat, short, or swelling) related to the charging of the battery 189.

For example, in operation 308, an MCU (e.g., the MCU 290 of FIG. 3) of the power management module may store the power gauge data in a memory (e.g., the memory 231 of FIG. 3) of a power gauge (e.g., the power gauge 230 of FIG. 2). In another example, in operation 308, the MCU of the power management module or the processor 120 may store the power gauge data in the memory.

For example, in operation 309, the electronic device 101 may set the electronic device 101 to the ship mode. For example, in operation 310, the electronic device 101 may control an operation of a switch (e.g., the switch 250 of FIG. 3) that forms a path to transmit the power from the battery 189. For example, the battery 189 may transmit power to components in the electronic device 101, such as the processor 120, an IC, a display module (e.g., the display module 160 of FIG. 1), a sound output module (e.g., the sound output module 155 of FIG. 1), a communication module (e.g., the communication module 190 of FIG. 1), an audio module (e.g., the audio module 170 of FIG. 1), a sensor module (e.g., the sensor module 176 of FIG. 1), a haptic module (e.g., the haptic module 179 of FIG. 1), and a camera module (e.g., the camera module 180 of FIG. 1), through the path transmitting the power. For example, in operation 310, when the path transmitting the power from the battery 189 is blocked as the power management module turns off the switch, a path through which a leakage current flows may be blocked.

For example, in operation 311, the electronic device 101 may identify whether a power key is input or an adapter (e.g., the adapter 300 of FIG. 3) is inserted. For example, the power management module of the electronic device 101 may receive a signal when a power key is input. When the power management module identifies that the power key is input, the power management module may cancel the ship mode of the electronic device 101.

In another example, when the adapter is inserted in operation 311, the power management module may identify that the adapter is inserted and the power management module may cancel the ship mode of the electronic device 101.

For example, when the power key is input or the adapter is inserted in operation 311, in operation 312, the electronic device 101 may control an operation of the switch. For example, the power management module of the electronic device 101 may control an operation of the switch, thereby, may form a path for transmitting the power from the battery 189 to components in the electronic device 101, such as the processor 120, an IC, a display module, a sound output module, a communication module, an audio module, a sensor module, a haptic module, or a camera module.

For example, in operation 313, the electronic device 101 may load the power gauge data from the memory. The electronic device 101 may load the power gauge data stored in the memory and the power gauge may identify the loaded power gauge data. As the electronic device 101 loads the power gauge data stored in the memory, the power gauge data may be prevented from being reset even when the electronic device 101 is set to the ship mode and then the ship mode is canceled.

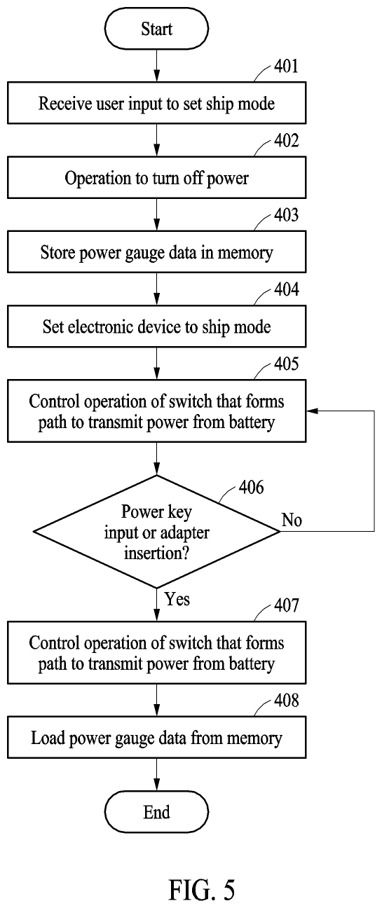

FIG. 5 is a flowchart illustrating example operations of an electronic device (e.g., the electronic device 101 of FIG. 1) according to various embodiments.

The embodiment illustrated in FIG. 5 may represent an operation flowchart when the electronic device 101 receives an input, e.g., an input from a user, to set to a ship mode.

Referring to FIG. 5, the electronic device 101 in various embodiments may receive a user input in operation 401. For example, the user input may be an input to set the ship mode. For example, an input to set the electronic device 101 to the ship mode may be received from the user through a user interface output on a display module (e.g., the display module 160 of FIG. 1) of the electronic device 101.

In another example, the electronic device 101 may include a separate input element for setting the electronic device 101 to the ship mode. For example, the user may input a key or a button to set the electronic device 101 to the ship mode.

For example, in operation 402, the electronic device 101 may perform an operation of turning off the power. In operation 403, the electronic device 101 may store the power gauge data in a memory (e.g., the memory 130 or 231 of FIG. 3). In operation 404, the electronic device 101 may set the electronic device 101 to the ship mode. In operation 405, the electronic device 101 may control an operation of a switch (e.g., the switch 250 of FIG. 3) that forms a path for transmitting power from a battery (e.g., the battery 189 of FIG. 1). For example, the power management module may block the path for transmitting the power from the battery 189 by turning off the switch.

In operation 406, whether a power key is input or an adapter (e.g., the adapter 300 of FIG. 3) is inserted may be identified. When the power key is input or the adapter is inserted in operation 406, the electronic device 101 may control an operation of the switch in operation 407. In operation 408, the electronic device 101 may load the power gauge data stored in the memory.

The operations 402, 403, 404, 405, 406, 407, and 408 described above may be substantially the same as the operations 304, 308, 309, 310, 311, 312, and 313 of FIG. 4. Accordingly, even if a description is not repeated with respect to the operations 402, 403, 404, 405, 406, 407, and 408, the descriptions provided with reference to the operations 304, 308, 309, 310, 311, 312, and 313 of FIG. 4 may be equally applied.

In an embodiment, in operation 401, the electronic device 101 may identify a voltage of the battery 189 when receiving a user input to set the electronic device 101 to the ship mode. For example, in operation 404, the electronic device 101 may monitor a voltage of the battery 189 with a power management module (e.g., the power management module 188 of FIG. 1) after turning off the power of the electronic device 101. For example, in operation 404, the electronic device 101 may set the electronic device 101 to the ship mode by comparing the monitored voltage of the battery 189 with the voltage of the battery 189 when receiving the user input.

For example, when the monitored voltage of the battery 189 has decreased by a set margin voltage from the voltage of the battery 189 when receiving the user input, the electronic device 101 may set the electronic device 101 to the ship mode.

For example, as shown in FIG. 5, the margin voltage when the electronic device 101 receives the user input from the user to set the electronic device 101 to the ship mode may be different from the margin voltage to set the reference voltage in the embodiment shown in FIG. 4.

For example, in operation 404, the magnitude of the margin voltage may be set to be less than the margin voltage described with reference to FIG. 4, for example, 50 mV. Even when receiving the input to set the electronic device 101 to the ship mode from the user, a time to turn off the power of the electronic device 101 may be secured by setting the electronic device 101 to the ship mode based on a small margin voltage.

In an embodiment, in operation 404, the electronic device 101 may set the electronic device 101 to the ship mode based on a change in the voltage of the battery 189 within a set time period after turning off the power.

For example, after the power of the electronic device 101 is turned off, the voltage of the battery 189 may decrease due to a leakage current. The amount of voltage decrease of the battery 189 due to the leakage current may be significantly smaller than the voltage decrease of the battery 189 due to an operation of the electronic device 101. For example, the electronic device 101 may determine whether the power of the electronic device 101 is normally turned off using the decreased voltage magnitude of the battery 189 during the set time period.

For example, the amount of voltage decrease of the battery 189 within 24 hours from an operation of turning off the power of the electronic device 101 is less than or equal to 1 mV, the electronic device 101 may determine that the power of the electronic device 101 is normally turned off.

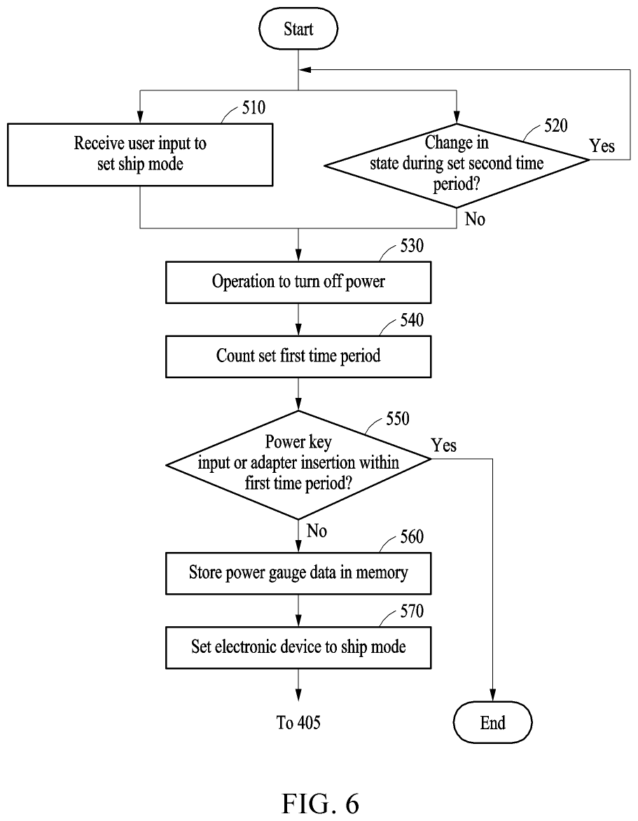

FIG. 6 is a flowchart illustrating example operations of an electronic device (e.g., the electronic device 101 of FIG. 1) according to various embodiments.

Referring to FIG. 6, the electronic device 101 in an embodiment may identify a signal to turn off the power of the electronic device 101.

For example, in operation 510, the electronic device 101 may receive a user input to set a ship mode. The user input received in operation 510 may represent a signal to turn off the power.

For example, in operation 520, the electronic device 101 may determine a change in a state of the electronic device 101 during a set second time period. When the state of the electronic device 101 is not changed during the set second time period, the electronic device 101 may output a signal to turn off the power.

For example, the electronic device 101 may determine that the state of the electronic device 101 has changed in the case of a screen touch input through a display module (e.g., the display module 160 of FIG. 1), a key input, such as a power key or a volume adjustment key, connection to a wired or wireless charger, an operating status of the electronic device 101 or an external environmental status collected by a sensor module (e.g., the sensor module 176 of FIG. 1), and a motion of a terminal (e.g., a motion of a terminal collected using a gyro sensor of the sensor module 176).

In operation 530, the electronic device 101 may perform an operation of turning off the power. For example, when the user input is received in operation 510 or when the state of the electronic device 101 is not changed during the second time period in operation 520, the electronic device 101 may perform an operation of turning off the power in operation 530. The electronic device 101 may terminate a running program, an OS, and the like and may block the power supplied to an element (e.g., the processor 120, the memory 130, the display module 160, and an IC) included in the electronic device 101.

The electronic device 101 may count a set first time period in operation 540. A processor (e.g., the processor 120 of FIG. 1) may transmit a control signal to a power management module (e.g., the power management module 188 of FIG. 1). The power management module 188 may count the set first time period based on the control signal. The electronic device 101 may determine the first time period based on a voltage magnitude of the battery 189 when identifying the signal to turn off the power. For example, the processor 120 may determine the first time period to have a positive correlation with the voltage magnitude of the battery 189.

For example, before the operation of turning off the power of operation 530 is completed, the processor 120 may determine the first time period based on the voltage magnitude of the battery 189. For example, the power control module 270 of the power management module 188 may determine the first time period based on the voltage magnitude of the battery 189 in operation 540.

In operation 550, the electronic device 101 may determine whether a power key is input or an adapter is inserted during the first time period.

When the power key is not input or the adapter is not inserted during the first time period in operation 550, the electronic device 101 may store the power gauge data in a memory (e.g., the memory 130 or 231 of FIG. 3) in operation 560. The power gauge data may include data on the state of the battery 189.

In operation 570, the electronic device 101 may set the electronic device 101 to the ship mode.

According to the example embodiment illustrated in FIG. 6, the electronic device 101 may minimize and/or reduce discharge of the battery 189 due to the leakage current and may increase a standby time in a power-off state.

For example, the total capacity of the battery 189 may be about 5,000 mAh, the voltage of the battery when the power is turned off may be about 4.0 V, the remaining capacity of the battery 189 when the power is turned off may be about 3,000 mAh, and a magnitude of the leakage current in the power-off state may be about 300 uA. After the electronic device 101 is set to the ship mode, the magnitude of the leakage current may be about 30 uA. After the voltage of the battery 189 reaches a V1 voltage (e.g., 2.6 V), the electronic device 101 may be set to the ship mode and after the electronic device 101 is set to the ship mode, the voltage of the battery 189 may reach a V2 voltage (e.g., 1.5 V) at which the battery 189 is overdischarged. In the example described above, a standby time taken for the voltage of the battery 189 to reach the V1 voltage may be about 13.9 months (3,000 mAh/300 uA=10,000 h), and a standby time taken to reach the V2 voltage after reaching the V1 voltage may be about 1.38 months (30 mAh/30 uA=1000 h). When the voltage of the battery 189 when turning off the power is about 4.0 V, the total standby time taken to reach the V2 voltage may be about 15.28 months.

The V1 voltage may be a reference voltage to determine whether to enter the ship mode to prevent and/or reduce overdischarge of the battery 189. The V2 voltage may be a voltage at which the battery 189 is overdischarged.

According to the example embodiment illustrated in FIG. 6, after the power of the electronic device 101 is turned off, a required time for the voltage of the battery 189 to reach the V1 voltage or the V2 voltage may increase.

For example, the total capacity of the battery 189 may be about 5,000 mAh, the voltage of the battery when the power is turned off may be about 4.0 V, the remaining capacity of the battery 189 when the power is turned off may be about 3,000 mAh, and a magnitude of the leakage current after the electronic device 101 is set to the ship mode may be about 30 uA. When the electronic device 101 is set to the ship mode after the power of the electronic device 101 is turned off and the set first time period (e.g., 24 hours, 48 hours, and the like) has elapsed, the time taken for the voltage of the battery 189, which is about 4.0 V, to reach the V1 voltage may be about 139 months (3,000 mAh/30 uA=100,000 h). The electronic device 101 may set the electronic device 101 to the ship mode when the set first time period has elapsed after the power is turned off, thereby, may increase the standby time taken for the voltage of the battery 189 to reach the V1 voltage.

The power control method according to various example embodiments may include: receiving an input to turn off the power of the electronic device, identifying a voltage of the battery based on receiving the input, determining a reference voltage to enter a ship mode to prevent and/or reduce discharge of the battery due to a leakage current based on a set margin voltage and a voltage of the battery when receiving the input, turning off the power of the electronic device, monitoring the voltage of the battery after turning off the power of the electronic device, and setting the electronic device to the ship mode based on a monitored voltage of the battery and the reference voltage.

The setting the electronic device to the ship mode may include storing power gauge data related to a state of the battery in the memory.

The power control method may further include, based on a power key being input or an adapter being inserted in the ship mode, loading the power gauge data stored in the memory.

The setting the electronic device to the ship mode may include setting the electronic device to the ship mode based on the monitored voltage of the battery being maintained to be less than or equal to the reference voltage for more than or equal to a set debounce time.

The power control method may further include controlling the electronic device to prevent or block the electronic device from being set to the ship mode before the input is received.

The setting the electronic device to the ship mode may include controlling an operation of the switch connected to the battery .

The determining the reference voltage may include determining the reference voltage based on a voltage magnitude obtained by subtracting the margin voltage from the voltage of the battery based on receiving the input, wherein the reference voltage is greater than or equal to a cut-off voltage set to prevent and/or reduce overdischarge of the battery.

The power control method according to various example embodiments may include: receiving an input to set the electronic device to a ship mode to prevent and/or reduce discharge of the battery due to a leakage current, turning off the power of the electronic device, storing power gauge data related to a state of the battery in the memory, and setting the electronic device to the ship mode.

The setting the electronic device to the ship mode may include controlling the switch connected to the battery.

The power control method may further include loading the power gauge data based on a power key being input or an adapter being inserted in the ship mode.

The setting the electronic device to the ship mode may set the electronic device to the ship mode by monitoring the voltage of the battery after turning off the power of the electronic device, and comparing the monitored voltage of the battery to the voltage of the battery based on receiving the input.

The setting the electronic device to the ship mode may include setting the electronic device to the ship mode based on a change in the voltage of the battery within a set time period after turning off the power of the electronic device.

The power control method may further include controlling the electronic device to prevent setting to the ship mode before the input is received.

The electronic device according to various example embodiments may include: a battery, at least one processor, comprising processing circuitry, and a power management module comprising power management circuitry configured to control power output by the battery, wherein at least one processor, individually and/or collectively, may be configured to: receive an input to turn off the power of the electronic device, identify a voltage of the battery based on receiving the input, determining a reference voltage to enter a ship mode to prevent and/or reduce discharge of the battery due to a leakage current based on a set margin voltage and a voltage of the battery based on receiving the input, and turn off the power of the electronic device, wherein the power management module may be further configured to: monitor the voltage of the battery after turning off the power of the electronic device, and set the electronic device to the ship mode based on a monitored voltage of the battery and the reference voltage.

The power management module may be configured to store power gauge data related to a state of the battery in the memory.

At least one processor, individually and/or collectively, may be configured to load the power gauge data stored in the memory based on a power key being input or an adapter being inserted in the ship mode.

The power management module may be configured to set the electronic device to the ship mode based on the monitored voltage of the battery being maintained to be less than or equal to the reference voltage for more than or equal to a set debounce time.

At least one processor, individually and/or collectively, may be configured to prevent the electronic device from being set to the ship mode before the input is received.

The power management module may be configured to control an operation of a switch connected to the battery.

At least one processor, individually and/or collectively, may be configured to: determine the reference voltage based on a voltage magnitude obtained by subtracting the margin voltage from the voltage of the battery based on receiving the input, wherein the reference voltage is greater than or equal to a cut-off voltage set to prevent and/or reduce overdischarge of the battery.

The power control method according to various example embodiments may include: identifying a signal to turn off power of an electronic device, turning off the power of the electronic device, counting a set first time period from when the signal to turn off the power is identified, setting the electronic device to a ship mode to prevent and/or reduce discharge of a battery due to a leakage current after the first time period has elapsed.

The identifying the signal to turn off the power of the electronic device may include: determining a change in a state of the electronic device during a set second time period, and based on the state of the electronic device not being changed during the second time period, outputting the signal to turn off the power.

The setting the ship mode may include storing power gauge data related to a state of the battery in a memory.

The power control method may further include, based on a power key being input or an adapter being inserted in the ship mode, loading the power gauge data stored in the memory.

The first time period may be set to have a positive correlation with a voltage magnitude of the battery when identifying the signal to turn off the power.

The setting to the ship mode may include controlling an operation of a switch connected to the battery.

The electronic device according to embodiments may be one of various types of electronic devices. The electronic device may include, for example, a portable communication device (e.g., a smartphone), a computer device, a portable multimedia device, a portable medical device, a camera, a wearable device, a home appliance device, or the like. According to an embodiment of the disclosure, the electronic device is not limited to those described above.

It should be appreciated that embodiments of the disclosure and the terms used therein are not intended to limit the technological features set forth herein to particular embodiments and include various changes, equivalents, or replacements for a corresponding embodiment. In connection with the description of the drawings, like reference numerals may be used for similar or related components. It is to be understood that a singular form of a noun corresponding to an item may include one or more of the things, unless the relevant context clearly indicates otherwise. As used herein, “A or B,” “at least one of A and B,” “at least one of A or B,” “A, B or C,” “at least one of A, B and C,” and “at least one of A, B, or C,” each of which may include any one of the items listed together in the corresponding one of the phrases, or all possible combinations thereof. Terms such as “1st,” “2nd,” or “first” or “second” may simply be used to distinguish the component from other components in question, and do not limit the components in other aspects (e.g., importance or order). It is to be understood that if an element (e.g., a first element) is referred to, with or without the term “operatively” or “communicatively,” as “coupled with,” “coupled to,” “connected with,” or “connected to” another element (e.g., a second element), the element may be coupled with the other element directly (e.g., by wire), wirelessly, or via a third element.

As used in connection with embodiments of the disclosure, the term “module” may include a unit implemented in hardware, software, or firmware, or any combination thereof, and may interchangeably be used with other terms, for example, “logic,” “logic block,” “part,” or “circuitry.” A module may be a single integral component, or a minimum unit or part thereof, adapted to perform one or more functions. For example, according to an embodiment, the module may be implemented in a form of an application-specific integrated circuit (ASIC).

Embodiments as set forth herein may be implemented as software (e.g., the program 140) including one or more instructions that are stored in a storage medium (e.g., an internal memory 136 or an external memory 138) that is readable by a machine (e.g., the electronic device 101). For example, a processor (e.g., the processor 120) of the machine (e.g., the electronic device 101) may invoke at least one of the one or more instructions stored in the storage medium and execute it. This allows the machine to be operated to perform at least one function according to the at least one instruction invoked. The one or more instructions may include code generated by a compiler or code executable by an interpreter. The machine-readable storage medium may be provided in the form of a non-transitory storage medium. Here, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to embodiments of the disclosure may be included and provided in a computer program product. The computer program product may be traded as a product between a seller and a buyer. The computer program product may be distributed in the form of a machine-readable storage medium (e.g., compact disc read-only memory (CD-ROM)), or be distributed (e.g., downloaded or uploaded) online via an application store (e.g., PlayStore™), or between two user devices (e.g., smartphones) directly. If distributed online, at least part of the computer program product may be temporarily generated or at least temporarily stored in the machine-readable storage medium, such as a memory of the manufacturer's server, a server of the application store, or a relay server.

According to embodiments, each component (e.g., a module or a program) of the above-described components may include a single entity or multiple entities, and some of the multiple entities may be separately disposed in different components. According to embodiments, one or more of the above-described components may be omitted, or one or more other components may be added. Alternatively or additionally, a plurality of components (e.g., modules or programs) may be integrated into a single component. In such a case, according to embodiments, the integrated component may still perform one or more functions of each of the plurality of components in the same or similar manner as they are performed by a corresponding one of the plurality of components before the integration. According to embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. A power control method comprising:
receiving an input to turn off power of an electronic device;
identifying a voltage of a battery based on receiving the input;
determining a reference voltage to enter a ship mode to prevent and/or or reduce discharge of the battery due to a leakage current based on a set margin voltage and a voltage of the battery based on receiving the input;
turning off the power of the electronic device;
monitoring the voltage of the battery after turning off the power of the electronic device; and
setting the electronic device to the ship mode based on a monitored voltage of the battery and the reference voltage.

2. The power control method of claim 1, wherein the setting of the electronic device to the ship mode comprises:
storing power gauge data related to a state of the battery in a memory.

3. The power control method of claim 2, further comprising:
based on a power key being input or an adapter being inserted in the ship mode, loading the power gauge data stored in the memory.

4. The power control method of claim 1, wherein the setting of the electronic device to the ship mode comprises:
setting the electronic device to the ship mode based on the monitored voltage of the battery being maintained to be less than or equal to the reference voltage for more than or equal to a set debounce time.

5. The power control method of claim 1, further comprising:
controlling the electronic device to prevent the electronic device from being set to the ship mode before the input is received.

6. The power control method of claim 1, wherein the setting of the electronic device to the ship mode comprises:
controlling a switch connected to the battery controlling a path for transmitting power to the electronic device.

7. The power control method of claim 1, wherein the determining of the reference voltage comprises:
determining the reference voltage based on a voltage magnitude obtained by subtracting the margin voltage from the voltage of the battery based on receiving the input, wherein the reference voltage is greater than or equal to a cut-off voltage that is set to prevent and/or reduce overdischarge of the battery.

8. A power control method comprising:
receiving an input to set an electronic device to a ship mode to prevent and/or reduce discharge of a battery due to a leakage current;
turning off power of the electronic device;
storing power gauge data related to a state of the battery in a memory; and
setting the electronic device to the ship mode.

9. The power control method of claim 8, wherein the setting of the electronic device to the ship mode comprises:
setting the electronic device to the ship mode by monitoring the voltage of the battery after turning off the power of the electronic device and comparing the monitored voltage of the battery to the voltage of the battery based on receiving the input.

10. The power control method of claim 8, wherein the setting of the electronic device to the ship mode comprises:
setting the electronic device to the ship mode based on a change in the voltage of the battery within a set time period after turning off the power of the electronic device.

11. A power control method comprising:
identifying a signal to turn off power of an electronic device;
turning off the power of the electronic device;
counting a set first time period from when the signal to turn off the power is identified;
setting the electronic device to a ship mode to prevent and/or reduce discharge of a battery due to a leakage current after the first time period has elapsed.

12. The power control method of claim 11, wherein the identifying of the signal to turn off the power of the electronic device comprises:
determining a change in a state of the electronic device during a set second time period; and
based on the state of the electronic device not being changed during the second time period, outputting the signal to turn off the power.

13. The power control method of claim 11, wherein the setting of the ship mode comprises:
storing power gauge data related to a state of the battery in a memory.

14. The power control method of claim 13, further comprising:
based on a power key being input or an adapter being inserted in the ship mode, loading the power gauge data stored in the memory.

15. The power control method of claim 11, wherein the first time period is set to have a positive correlation with a voltage magnitude of the battery based on identifying the signal to turn off the power.
